(19) United States
(12) Patent Application Publication
(10) Pub. No.: US 2023/0123033 A1
(43) Pub. Date: Apr. 20, 2023

(54) COLOR FILTER SUBSTRATE, MANUFACTURING METHOD THEREOF, AND LIQUID CRYSTAL DISPLAY PANEL

(71) Applicant: WUHAN CHINA STAR OPTOELECTRONICS TECHNOLOGY CO., LTD., Wuhan (CN)

(72) Inventor: Jianlong HUANG, Wuhan (CN)

(73) Assignee: WUHAN CHINA STAR OPTOELECTRONICS TECHNOLOGY CO., LTD., Wuhan (CN)

(21) Appl. No.: 17/046,805

(22) PCT Filed: Sep. 16, 2020
(86) PCT No.: PCT/CN2020/115636

§ 371 Date: Oct. 12, 2020

(30) Foreign Application Priority Data
Aug. 20, 2020 (CN) 202010842146.6

(51) Int. Cl. G02F 1/1335; G02F 1/1339; G02F 1/1368; G03F 7/00

(52) U.S. Cl. CPC G02F 1/133516; G02F 1/133519; G02F 1/13394; G02F 1/13396; G02F 1/1368; G03F 7/0007; G02F 1/133512; G02F 1/1337

(57) ABSTRACT

A color filter substrate and a display panel are provided. A photoresist layer is provided in a peripheral region of the color filter substrate. A plurality of photoresist layers are stacked on each other to optimize a film structure of the color filter substrate, enhance a support of a film, and reduce a degree of depression in the peripheral region in an ODF process. The color filter substrate with optimized film structure has simple manufacturing process, and quality of the display panel can be improved without changing a structural design of a display region of an original film.

### FIELD OF INVENTION

The present invention relates to the field of liquid crystal display technologies, and in particular, to a color filter substrate, a manufacturing method thereof, and a liquid crystal display panel.

### BACKGROUND OF INVENTION

Current liquid crystal display (LCD) panels usually comprise a thin film transistor (TFT) substrate and a color filter (CF) substrate. FIG. 1 illustrates a cause of yellowing around a current panel. As shown in FIG. 1, the TFT substrate comprises a base substrate 1 and a TFT film layer 8. The CF substrate comprises a base substrate 2, a black matrix (BM) light shielding layer 5, and a color photoresist 9. The TFT substrate and the CF substrate are assembled in position, and a liquid crystal layer 6 is in a middle. A region with the liquid crystal layer 6 is a display region, which comprises an abnormal display region C and a normal display region D. Other regions are non-display regions. The non-display regions comprise a dummy region A (also called a transition region) of the display region and an outer lead bonding region B (OLB). The TFT substrate and the CF substrate are combined by a sealing sealant 4. Spacers 3 and spacers 7 are respectively provided in the display region and the dummy region for support to keep a panel structure flat and maintain a same cell gap.

### Technical Problem

In a manufacturing process of a liquid crystal panel, when implementing one drop filling (ODF, a liquid crystal dropping process), a vacuum assembly process is used to vacuum. At this time, a vacuum chamber will appear in a dummy region between two substrates. Current CF film structure in the dummy region is not sufficiently supported. Under an action of an atmospheric pressure outside the substrate, the substrate in the dummy region is prone to dent, which causes neighboring panels to be tilted up, a “seesaw” effect occurs, flatness of the panel is not good, and an edge of an LCD display appears yellow.

### Technical Solution

The present invention provides a color filter substrate, a manufacturing method thereof, and a liquid crystal display panel. The color filter substrate improves a film structure in a peripheral region, improves supportability of a film, prevents denting in the peripheral region, and improves yellowing of a periphery of the liquid crystal display panel.

The present invention first provides the color filter substrate comprising a display region and a peripheral region, wherein the peripheral region is provided with a light shielding layer and a photoresist layer, the photoresist layer in the peripheral region comprises a plurality of color photoresists, the plurality of color photoresists are stacked, and projections of the plurality of color photoresists in a direction perpendicular to the color filter substrate overlap with each other.

In some embodiments, the photoresist layer in the peripheral region comprises at least two types of photoresists selected from a group of a blue photoresist, a green photoresist, and a red photoresist.

In some embodiments, the peripheral region is further provided with an over coat layer and a spacer layer. The light shielding layer, the photoresist layer, the over coat layer (OC layer), and a spacer layer are stacked in the peripheral region, and projections of the light shielding layer, the photoresist layer, the over coat layer, and the spacer layer in a direction perpendicular to the color filter substrate overlap with each other.

In some embodiments, the display region of the color filter substrate is provided with a light shielding layer and a photoresist layer, the light shielding layer in the display region is a black matrix structure, the black matrix structure divides the color filter substrate into a plurality of pixel regions, and the photoresist layer of the display region is distributed in the pixel regions.

In some embodiments, the display region of the color filter substrate is further provided with the over coat layer, a common electrode layer, and a first alignment film layer.

In some embodiments, the light shielding layer of the peripheral region is continuously distributed, and a thickness of the light shielding layer of the peripheral region is equal to a thickness of a black matrix in the display region.

The present invention further provides a liquid crystal display panel comprising a thin film transistor substrate and the above-mentioned color filter substrate disposed in parallel, and a liquid crystal layer disposed between the two substrates, wherein the liquid crystal layer is distributed at a position corresponding to the display region of the color filter substrate.

In some embodiments, the spacer layer is provided with a plurality of spacers, and in the peripheral region, gap distances between the plurality of spacers and the thin film transistor substrate are same as each other.

The present invention further provides a display device comprising the above-mentioned liquid crystal panel.

The present invention further provides a manufacturing method of a color filter substrate, comprising following steps:

forming a light shielding layer on a display region and a peripheral region of a base substrate, wherein the light shielding layer in the display region is etched into a matrix distribution pattern, and a substrate of the display region is divided into a plurality of pixel regions;

forming a photoresist layer on the display region, wherein different color photoresists of the photoresist layer of the display region are distributed in the pixel regions, and the different color photoresists of the peripheral region are stacked;

forming an over coat layer on the photoresist layer; and

forming a spacer layer on the over coat layer of the peripheral region,

wherein the light shielding layer, the photoresist layer, the over coat layer, and the spacer layer of the peripheral region are stacked.

In some embodiments, the spacer layer in the peripheral region is provided with a plurality of spacers, and patterns of the plurality of spacers are formed by a semi-permeable mask process.

### Beneficial Effect

In the present invention, by adding a photoresist layer to a color filter substrate in a peripheral region, a plurality of the photoresist layers are stacked to optimize a film structure of the color filter substrate, enhance a film support, reduce a degree of depression in the peripheral region in an ODF process, and improve mura (unevenness) in a peripheral of a LCD panel. The color filter substrate with optimized film structure is simple to process and does not change original design of a display region of the film layer, and has a wide range of applications.

### DESCRIPTION OF DRAWINGS

The technical solution and other beneficial effects of the present invention will be made apparent by following detailed description of embodiments of the present invention in conjunction with accompanying drawings.

FIG. 1 is a schematic view of a cause of yellowing around a display panel in the prior art.

FIG. 2 is a schematic structural view of a peripheral region of a CF film layer provided by Embodiment 1 of the present invention, wherein A is a cross-sectional view of a structure of the peripheral region of the CF film layer, and B is a top view of the structure of the peripheral region of the CF film layer. Quadrilateral, hexagonal, and circular shapes in FIG. 2B do not represent an actual cross-sectional shape of the film layer, and are only used as a schematic to distinguish each film layer.

FIG. 3 is an overall schematic structural view of the CF film layer provided by Embodiment 2 of the present invention.

FIG. 4 is a schematic structural view of a display panel provided by Embodiment 3 of the present invention.

FIG. 5 is a schematic view of a state of an ODF process of the display panel provided by Embodiment 3 of the present invention.

### DETAILED DESCRIPTION OF PREFERRED EMBODIMENTS

The following will clearly and completely describe the technical solutions in the embodiments of the present invention with reference to the drawings in the embodiments of the present invention. Obviously, the described embodiments are only a part of the embodiments of the present invention, rather than all the embodiments. Based on the embodiments in the present invention, all other embodiments obtained by those skilled in the art without creative work are within the protection scope of the present invention.

In the description of the present invention, it is to be understood that the terms “length,” “width,” “thickness,” “upper,” “lower,” and the like are used in the orientations and positional relationships indicated in the drawings for convenience in describing the present invention and for simplicity in description, and are not intended to indicate or imply that the referenced devices or elements must have a particular orientation, be constructed in a particular orientation, and be operated in a particular manner, and are not to be construed as limiting the present invention. Furthermore, the terms “first” and “second” are used for descriptive purposes only and are not to be construed as indicating or implying relative importance or implicitly indicating the number of technical features indicated. Thus, features defined as “first”, “second”, may explicitly or implicitly include one or more of the described features. In the description of the present application, “plurality” means two or more unless specifically limited otherwise.

The following disclosure provides different implementations or examples to implement the present invention. In order to simplify the disclosure of the present invention, specific examples are described below. Of course, they are only examples and are not intended to limit the present invention. In addition, the present invention may repeat reference numerals and/or reference letters in different examples. Such repetition is for the purpose of simplification and clarity, and does not indicate the relationship between the various embodiments and/or settings discussed. In addition, the present invention provides examples of various specific processes and materials, but those of ordinary skill in the art may be aware of the application of other processes and/or the use of other materials.

### Embodiment 1

Referring to FIG. 2, Embodiment 1 provides a color filter substrate comprising a display region 10 and a peripheral region 20. A light shielding layer 22 and a photoresist layer are provided on a surface of the peripheral region 20 of a base substrate 11. The photoresist layer comprises a first photoresist 23 and a second photoresist 24. The first photoresist 23 and the second photoresist 24 are stacked, and projections of the first photoresist 23 and the second photoresist 24 in a direction perpendicular to the color filter substrate (liquid crystal display panel) overlap with each other. For example, the second photoresist 24 covers a surface of the first photoresist 23.

The photoresist layer in the peripheral region 20 comprises at least two types of photoresists selected from a group of a blue photoresist, a green photoresist, and a red photoresist. Specifically, the first photoresist 23 and the second photoresist 24 are photoresists with different colors. In some embodiments, the first photoresist 23 is a green photoresist, and the second photoresist 24 is a blue photoresist, or, the first photoresist 23 and the second photoresist 24 are a combination of two other color photoresists.

Photoresist types of the photoresist layer can be determined according to a manufacturing process of the photoresist layer of the color filter substrate, especially according to a manufacturing process of a photoresist layer 13 in the display region 10. For example, according to the manufacturing process of the photoresist layer 13 in the display region 10, a green photoresist is first formed, and then a blue photoresist is formed, then the first photoresist 23 in the corresponding peripheral region 20 is a green photoresist, the second photoresist 24 is a blue photoresist, and the two are stacked.

In some embodiments, the peripheral region 20 is further provided with an over coat layer 25 and a spacer layer 26. The over coat layer 25 is a planarization layer, and the spacer layer 26 serves as a secondary spacer. Referring to FIG. 2B, the light shielding layer 22, the photoresist layer 23, the photoresist layer 24, the over coat layer 25, and the spacer layer 26 are stacked in the peripheral region 20, and projections of the layers in a direction perpendicular to the color filter substrate (LCD panel) overlap with each other. Quadrilateral, hexagonal, and circular shapes in FIG. 2B do not represent an actual cross-sectional shape of the film layer, and are only for schematically distinguishing each film layer.

In some embodiments, a difference between a sum of a thickness of all the film layers of the color filter substrate in the peripheral region and a sum of a thickness of all the film layers of the color filter substrate in the display region is less than a preset threshold, so that the thicknesses of the two is roughly equal. The preset threshold can be determined according to a design of a cell gap and a display effect of the liquid crystal display panel.

In the color filter substrate, a thickness of the first photoresist 23 and a thickness of the second photoresist layer 24 can be adjusted to adjust an overall film thickness of the peripheral region 20 and the display region 10, and reduce a gap between the peripheral region 20 and the display region 10.

In some embodiments, thicknesses of individual film layers of the first photoresist 23 and the second photoresist 24 are 2.0-3.0 μm (micrometers), respectively, and a thickness of the first photoresist 23 and the second photoresist 24 after being stacked is about 3.5-5.0 μm.

In some embodiments, the spacer layer 26 is stacked on a surface of the over coat layer 25.

### Embodiment 2

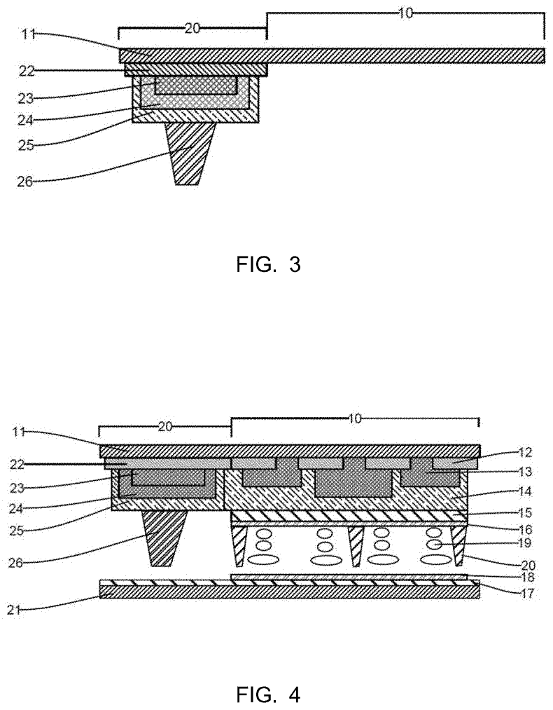

Referring to FIG. 2 and FIG. 3, Embodiment 2 of the present invention provides the color filter substrate comprising the display region 10 and the peripheral region 20. The peripheral region 20 is same as in Embodiment 1. Further, a light shielding layer 12 and the photoresist layer 13 are provided in the display region 10. The light shielding layer 12 of the display region 10 comprises a black matrix structure, and the base substrate 11 is divided into a plurality of pixel regions. The photoresist layer 13 comprises a red photoresist R, a green photoresist G, and a blue photoresist B, and the photoresists are distributed in the pixel region.

The display region 10 of the color filter substrate is further provided with an over coat layer 14, a common electrode layer 15, and a first alignment film layer 16.

The light shielding layer of the peripheral region 20 is continuously distributed, and a thickness of the light shielding layer 22 of the peripheral region 20 is equal to a thickness of the black matrix (light shielding layer 12) in the display region 10.

In some embodiments, the light shielding layer and the over coat layer of the display region 10 and the peripheral region 20 are formed in a same manufacturing process. For example, in a CF substrate manufacturing process, the light shielding layer is formed on the base substrate 11 to cover the display region 10 and the peripheral region 20, and then the light shielding layer of the display region 10 is formed into a black matrix pattern to form the light shielding layer 12, and the light shielding layer in the peripheral region 20 is continuously distributed to form the light shielding layer 22. For example, in the CF substrate manufacturing process, after a color photoresist film layer is formed, the over coat layer is formed to cover the display region 10 and the peripheral region 20 to form the over coat layer 14 and the over coat layer 25. The light shielding layer and the over coat layer in the embodiment can be implemented according to processes known in the art.

### Embodiment 3

Embodiment 3 provides the liquid crystal display panel. Referring to FIG. 3 and FIG. 4, the liquid crystal display panel comprises a thin film transistor substrate and the color filter substrate disposed in parallel, and a liquid crystal layer distributed between the two substrates. The color filter substrate of the liquid crystal display panel comprises a same structure as Embodiment 2. The thin film transistor substrate comprises a base substrate 21, and a TFT film layer 17 is provided on the base substrate 21. A second alignment film 18 is provided on the TFT film layer 17 corresponding to the display region 10. The second alignment film 18 is opposite to the first alignment film 16 of the color filter substrate, and a liquid crystal layer 19 is provided between the first alignment film 16 and the second alignment film 18. A gap of the liquid crystal layer 19 may be provided with a spacer 20.

In some embodiments, the spacer 26 in the color filter substrate is provided with an opening region on a mask plate in a photoresist exposure and development process, so a spacer pattern can be formed after the photoresist exposure and development process. Therefore, a plurality of the spacers 26 have more than one contact point with the thin film transistor substrate. An arrangement of the contact points and the spacer pattern are determined according to a topography of the thin film transistor substrate and the design of the cell gap, so that the color filter substrate and the thin film transistor substrate are aligned accurately, and a film thickness of the display region 10 and a film thickness of the peripheral region 20 are consistent. In the peripheral region 20, gap distances between the plurality of spacers 26 and the thin film transistor substrate are same as each other. Patterns of the plurality of spacers 26 can be formed by a semi-permeable film mask process.

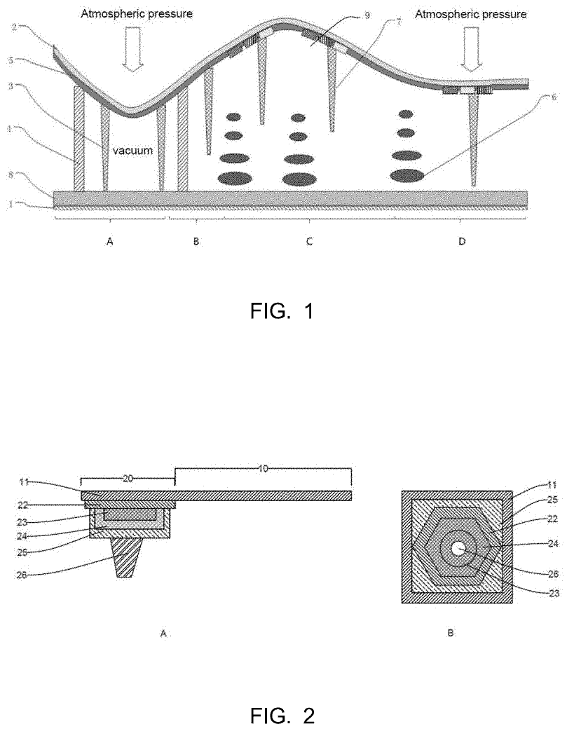

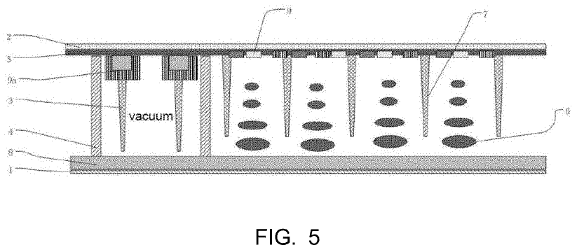

Referring to FIG. 5, compared with the prior art panel shown in FIG. 1, the liquid crystal display panel provided by the embodiment of the present invention does not change other film structures, and still retains the TFT substrate (including the base substrate 1 and the TFT film layer 8), the CF substrate (including the base substrate 2, the black matrix (BM) light shielding layer 5, and color photoresist 9). The TFT substrate and the CF substrate are assembled in position, with a liquid crystal layer 6 in a middle. The TFT substrate and the CF substrate are combined by a sealing sealant 4. The spacers 3 and the spacers 7 are respectively provided in the display region and the peripheral region for support. On the basis, by optimizing the film structure of the color filter substrate in the peripheral region, a photoresist layer 9a, such as a two-color photoresist or a multi-color photoresist layer stack, improves supportability of the film. In an ODF process, even if there is a vacuum cavity, the color filter substrate film can effectively support the substrate, thereby reducing a difference in cell thickness between the peripheral region and the display region, and effectively prevent a yellowing phenomenon caused by a depression in the peripheral region, and improve display quality of the panel.

The embodiment of the present invention further provides a manufacturing method of the color filter substrate, which comprises following steps:

forming the light shielding layer on the display region 10 and the peripheral region 20 of the base substrate 11, wherein the light shielding layer 12 in the display region 10 is etched into a matrix distribution pattern, and a substrate of the display region 10 is divided into the plurality of pixel regions; and wherein the light shielding layer 22 of the peripheral region 20 maintains a continuous distribution or an etching pattern.

forming the photoresist layer on the light shielding layer in all the regions of the base substrate 11, wherein different color photoresists (RGB) of the photoresist layer of the display region are distributed in the pixel regions, and the different color photoresists of the peripheral region 20 are stacked;

forming the over coat layer on the photoresist layer in all the regions of the base substrate 11, covering the display region 10 and the peripheral region 20 to form the over coat layer 14 and the over coat layer 25, respectively; and

forming the spacer layer 26 on the over coat layer 14 of the peripheral region 20,

wherein the light shielding layer 22, the photoresist layer 23, 24, the over coat layer 25, and the spacer layer 26 of the peripheral region 20 are stacked, and the projections of the layers in a direction perpendicular to the panel overlap with each other.

In some embodiments, a photoresist stacking order in the peripheral region 20 is consistent with a coating order of the photoresist layer in the display region 10. The photoresist of the peripheral region 20 and the photoresist of the display region 10 are preferably formed in a single manufacturing process. For example, the display region 10 is first made of a G photoresist, and then made of a B photoresist. Correspondingly, when the G photoresist is formed in the display region 10, a G photoresist layer is also formed in the peripheral region 20, and then when the B photoresist is formed in the display region 10, a B photoresist layer is also formed in the peripheral region 20. The B photoresist layer is stacked on a surface of the G photoresist layer.

In some embodiments, the manufacturing method of the color filter substrate further comprises sequentially disposing the common electrode layer 15 and the first alignment film layer 16 on the surface of the over coat layer 16 of the display region 10. For example, the common electrode layer 15 is an ITO metal layer.

The embodiment of the present invention further comprises manufacturing the liquid crystal display panel, respectively forming the color filter substrate and the thin film transistor substrate, and then aligning the two substrates to implement the ODF process.

Materials and forming processes of the film layers of the color filter substrate and the thin film transistor substrate in the embodiments of the present invention are not particularly limited, and it can be made by using materials and processes known in the art to form the film structure of the embodiment of the present invention to achieve a purpose of the present invention.

The color filter substrate and the liquid crystal display panel provided by the embodiments of the present invention are described in detail above. In the article, specific examples are used to illustrate the principle and implementation of the present invention. The description of the above embodiments is only used to help understand the technical solution of the present invention and its core idea. Those of ordinary skill in the art should understand that they can still modify the technical solutions described in the foregoing embodiments, or equivalently replace some of the technical features. However, these modifications or replacements do not make the essence of the corresponding technical solutions deviate from the scope of the technical solutions of the various embodiments of the present invention.

1. A color filter substrate, comprising a display region and a peripheral region, wherein the peripheral region is provided with a light shielding layer and a photoresist layer, the photoresist layer in the peripheral region comprises a plurality of color photoresists, the plurality of color photoresists are stacked, and projections of the plurality of color photoresists in a direction perpendicular to the color filter substrate overlap with each other.

2. The color filter substrate as claimed in claim 1, wherein the photoresist layer in the peripheral region comprises at least two types of photoresists selected from a group of a blue photoresist, a green photoresist, and a red photoresist.

3. The color filter substrate as claimed in claim 1, wherein the peripheral region is further provided with an over coat layer and a spacer layer.

4. The color filter substrate as claimed in claim 1, wherein the light shielding layer, the photoresist layer, an over coat layer, and a spacer layer are stacked in the peripheral region, and projections of the light shielding layer, the photoresist layer, the over coat layer, and the spacer layer in the direction perpendicular to the color filter substrate overlap with each other.

5. The color filter substrate as claimed in claim 1, wherein the display region of the color filter substrate is provided with a light shielding layer and a photoresist layer.

6. The color filter substrate as claimed in claim 5, wherein the light shielding layer of the display region is a black matrix structure, the black matrix structure divides the color filter substrate into a plurality of pixel regions, and the photoresist layer of the display region is distributed in the pixel regions.

7. The color filter substrate as claimed in claim 6, wherein the light shielding layer of the peripheral region is continuously distributed, and a thickness of the light shielding layer of the peripheral region is equal to a thickness of a black matrix in the display region.

8. The color filter substrate as claimed in claim 6, wherein the display region of the color filter substrate is further provided with an over coat layer, a common electrode layer, and a first alignment film layer.

9. A liquid crystal display panel, comprising a thin film transistor substrate and a color filter substrate disposed in parallel, and a liquid crystal layer disposed between the two substrates, wherein the color filter substrate is the color filter substrate according to claim 1.

10. The liquid crystal display panel as claimed in claim 9, wherein the peripheral region is further provided with the over coat layer and the spacer layer, the light shielding layer, the photoresist layer, the over coat layer, and the spacer layer are stacked in the peripheral region, the projections of the light shielding layer, the photoresist layer, the over coat layer, and the spacer layer in the direction perpendicular to the color filter substrate overlap with each other, the spacer layer is provided with a plurality of spacers, and in the peripheral region, gap distances between the plurality of spacers and the thin film transistor substrate are the same as each other.

11. A manufacturing method of a color filter substrate, comprising following steps:
forming a light shielding layer on a display region and a peripheral region of a base substrate, wherein the light shielding layer in the display region is etched into a matrix distribution pattern to form a black matrix structure, and a substrate of the display region is divided into a plurality of pixel regions;
forming a photoresist layer on the light shielding layer of the display region and of the peripheral region, wherein different color photoresists of the photoresist layer of the display region are distributed in the pixel regions, and the different color photoresists of the peripheral region are stacked;
forming an over coat layer on the photoresist layer of the display region and of the peripheral region; and
forming a spacer layer on the over coat layer of the peripheral region,
wherein the light shielding layer, the photoresist layer, the over coat layer, and the spacer layer of the peripheral region are stacked.

12. The manufacturing method of the color filter substrate as claimed in claim 11, wherein the step of forming the light shielding layer on the display region and the peripheral region is a single manufacturing process, the light shielding layer in the display region is etched into the matrix distribution pattern, and the light shielding layer in the peripheral region is continuously distributed.

13. The manufacturing method of the color filter substrate as claimed in claim 11, wherein a thickness of the light shielding layer in the peripheral region is equal to a thickness of a black matrix in the display region.

14. The manufacturing method of the color filter substrate as claimed in claim 11, wherein the photoresist layer of the display region and the photoresist layer of the peripheral region are formed in a same manufacturing process.

15. The manufacturing method of the color filter substrate as claimed in claim 11, wherein the spacer layer in the peripheral region is provided with a plurality of spacers, and patterns of the plurality of spacers are formed by a semi-permeable mask process.
